(19) United States
(12) Patent Application Publication
(10) Pub. No.: US 2025/0273580 A1
(43) Pub. Date: Aug. 28, 2025

(54) POWER MODULE AND METHOD FOR PRODUCING A POWER MODULE

(71) Applicant: Robert Bosch GmbH, Stuttgart (DE)

(72) Inventor: Irfan Aydogmus, Nuertingen (DE)

(21) Appl. No.: 19/058,541

(22) Filed: Feb. 20, 2025

(30) Foreign Application Priority Data
Feb. 26, 2024 (DE) 10 2024 201 724.8

(51) Int. Cl. H01L 23/538; H01L 21/48; H01L 23/373; H01L 25/07

(52) U.S. Cl. CPC H01L 23/5385; H01L 21/4853; H01L 23/3735; H01L 25/072

(57) ABSTRACT

A power module with a circuit carrier, which includes a carrier substrate and an electrical insulation layer. The circuit carrier has a first conductor structure with an external contact region and at least one second conductor structure with at least one external contact region and a third conductor structure, which includes at least one external contact region, with semiconductor components arranged individually or in groups. The power module is assigned a multifunctional frame with a printed circuit board. Groups of semiconductor components are arranged in a first level, spatially separated from a second level in the multifunctional frame. The semiconductor components are electrically connected to one another by a first welded connection with introduction of at least one first spacer. The power module is electrically connected to the multifunctional frame by a sleeve connection with the introduction of at least one double-ended pin and at least one sleeve.

### FIELD

The present invention relates to a power module with a first circuit carrier made of a carrier substrate and a first conductor structure with an external contact region, at least one second conductor structure with at least one external contact region, and a further, third conductor structure, which comprises an external contact region, further with a first group of semiconductor components and a second group of semiconductor components. Furthermore, the present invention relates to a method for producing a power module.

### BACKGROUND INFORMATION

Germany Patent Application No. DE 11 2017 004 390 T5 describes a power module that has the following features: an insulating substrate having a front side to which a power semiconductor component is fastened; a base plate connected to a rear side of the insulating substrate; a housing fastened to the base plate and surrounding the insulating substrate; a cover fastened to the housing and forming a sealed region; and a silicone gel serving as a filling element, which fills the entire sealed region and has an internal stress that acts as a compressive stress.

Germany Patent Application No. DE 10 2014 219 998 B4 describes a power module, in particular for providing a phase current for an electric motor. The power module comprises a circuit carrier having a surface, at least two first contact faces on the surface, and at least two first power transistors, which each have a ground contact face. In each case, a first power transistor of the at least two first power transistors is arranged directly on one of the first contact faces and is electrically conductively connected directly to the relevant first contact face via its ground contact face. In addition, the power module comprises a second contact face on the surface and at least two second power transistors, which each have a ground contact face. The at least two second power transistors are arranged directly on the second contact face and are electrically conductively connected directly to the second contact face via their respective ground contact faces. Furthermore, the power module comprises at least two third contact faces on the surface, wherein the at least two second power transistors each have a further contact face on their sides facing away from the surface of the circuit carrier, and in each case one second power transistor of the at least two second power transistors is electrically conductively connected via its further contact face to one of the at least two third contact faces in each case. The at least two first contact faces and the at least two third contact faces are arranged alternately one after the other in a longitudinal direction of the power module, and the second contact face is arranged next to the at least two first contact faces and the at least two third contact faces, wherein the second contact face has at least two contact regions, wherein in each case one of the at least two contact regions is located next to one of the at least two first power transistors. The at least two first power transistors each have a further contact face on their sides facing away from the surface of the circuit carrier, and in each case one first power transistor of the at least two first power transistors is electrically conductively connected via its further contact face to the in each case one contact region, located next to it, of the at least two contact regions of the second contact face. In this case, the at least two contact regions of the second contact face and the at least two second power transistors are arranged alternately one after the other in the longitudinal direction.

European Patent No. EP 2 418 925 B1 describes an electrical contacting between a flexible film, which has at least one conductor track, and at least one electrical contact of a sensor device or control device. In this case, an end portion of the flexible film is electrically contacted by heat input at a contact point, wherein the end portion of the flexible film is placed against protruding electrical contacts at the contact point. The end portion of the flexible film is designed with a breaking wave shape, in particular as a deflection.

### SUMMARY

According to an example embodiment of the present invention, a power module is provided with a circuit carrier, which comprises a carrier substrate and an electrical insulation layer, wherein the circuit carrier has a first conductor structure with an external contact region and at least one second conductor structure with at least one external contact region and a further, third conductor structure, which comprises at least one external contact region, with semiconductor components arranged individually or in groups, wherein the power module is assigned a multifunctional frame with a printed circuit board, the groups of semiconductor components are arranged in a first level, which is spatially separated from a second level in the multifunctional frame, are electrically connected to one another by a first welded connection with the introduction of at least one spacer, wherein the power module is electrically connected to the multifunctional frame by a sleeve connection with the introduction of at least one double-ended pin and at least one sleeve.

A double-ended pin in the sense of the present invention is a pin or, for example, a bolt that is used as a connecting element to make a current flow between two electronic components possible. The double-ended pin according to the present invention has a central shaft, to which a mandrel is attached at both ends, the mandrels being arranged to have a plug-in shape, which makes easy and secure fastening in prepared openings in a printed circuit board (PCB) and a sleeve possible. The double-ended pin is, for example, inserted into a suitable opening in the part of the power module and/or of the printed circuit board of the multifunctional frame to be connected and is subsequently pressed in, hammered in or pressed in another way so that a mechanical and electrical connection is produced between the power module and the multifunctional frame. By pressing in the double-ended pin, the lowest possible electrical resistance is achieved, which makes low-loss current transmission between the connected components possible. In this context, press-fit pins are usually produced from conductive materials such as copper, aluminum or brass or alloys. A further function of the press-fit pins is producing a reliable and stable electrical connection. In addition, the use of press-fit pins as an electrical connection makes a modular structure between the power module and the multifunctional frame possible, which makes assembly, maintenance and repair easier than with an integrally bonded electrical connection. The advantage of press-fit pins is that they are connected using a comparatively low-invasive joining technique. In contrast to soldering processes, which often require higher temperatures and cause chemical reactions of the materials, double-ended pins make a very reliable connection over the lifetime of the module possible.

In the solution according to the present invention, a suitable opening is understood to be an opening in a sleeve. A sleeve is, for example, a cylindrical or tubular component with a through-hole. This hole is dimensioned such that a double-ended pin can be inserted. The sleeve has a bottom surface, wherein the bottom surface can be welded or soldered to the power module, for example.

In an advantageous example embodiment of the power module provided according to the present invention, the semiconductor components are arranged individually or in groups on a base of the power module.

In a further advantageous embodiment of the power module provided according to the present invention, the power module is connected to a cooling surface either via an adhesive connection, a first soldered connection, or a fourth welded connection.

In a further advantageous embodiment variant of the power module provided according to the present invention, the power module is connected to the multifunctional frame via a second welded connection and a third welded connection.

In a further advantageous embodiment variant of the power module provided according to the present invention, a first welded connection comprises a first weld layer, a second weld layer, and a third weld layer.

In a further advantageous possible embodiment of the power module provided according to the present invention, the multifunctional frame is arranged above or below the power module as viewed in the Z direction.

In a further advantageous possible embodiment of the power module according to the present invention, current-carrying components, in particular a T+ bridge and a T− bridge, are formed one above the other or next to one another in the multifunctional frame in such a way that a low-inductive connection is formed.

In a further advantageous possible embodiment of the power module according to the present invention, the one or more sleeves is/are connected to the power module via the second welded connection or a second soldered connection.

In a further advantageous possible embodiment of the power module according to the present invention, one or more double-ended pins have a first side and a second side.

Furthermore, the present invention relates to a method for producing a power module, in which
a first conductor structure with a first contact region,
at least one second conductor structure with at least one external contact region, and
a further, third conductor structure having an external contact region
   are provided, wherein
a multifunctional frame is assigned to the power module,
wherein an electrical connection of the power module to the multifunctional frame is made via at least one double-ended pin,
groups of semiconductor components are arranged in a first level, which are arranged spatially separated from a second level in the multifunctional frame,
wherein contact faces contacting the groups of semiconductor components are arranged in the second level.

In the example embodiments of the power module provided according to the present invention, the active surfaces and the layout surfaces are advantageously designed to be separate from one another. The arrangement according to the present invention of the multifunctional frame, which is arranged, for example, above the power module, results in a shift in the current conduction from the power module into the multifunctional frame arranged, for example, above it. This leads to an improved cooling option of the semiconductor components. In addition, since larger distances between the semiconductor components can be realized, improved cooling can be achieved. Due to the embodiment provided according to the present invention, it is also advantageous if current-carrying paths, such as a T+ bridge and/or a T− bridge, are laid in the multifunctional frame and are formed there one above the other or next to one another as a low-inductive connection. In particular, any switching losses can be reduced by the option of forming the current-carrying paths as low-inductive current paths.

The integrally bonded connection provided according to the present invention between the multifunctional frame and the semiconductor components accommodated on the base of the power module, for example MOSFETs, IGBTs, or diodes, or another electronic component, can produce an effective and robust electrical connection between the multifunctional frame, the contact faces that extend there, and the semiconductor components themselves. Advantageously, the present invention provides a combination of a sleeve connection for the signal line and a welded connection for high-current lines between the power module and the multifunctional frame. A simple assembly and disassembly of the power module from the multifunctional frame is realized by the sleeve connection proposed according to the present invention using sleeves.

The double-ended pin according to the present invention, with which the power module is electrically connected to the multifunctional frame, achieves a cost-effective and reliable joining connection.

### BRIEF DESCRIPTION OF THE DRAWINGS

Embodiments of the present invention are explained in greater detail with reference to the figures and the following description.

FIG. 1 is a plan view of a circuit carrier of a power module with a carrier substrate and a possible arrangement of semiconductor components, according to an example embodiment of the present invention.

FIG. 2 is a plan view of a power module with cooling surfaces and layout surfaces separated from one another, with laterally arranged regions for press-fit pins, according to an example embodiment of the present invention.

FIG. 3 is an exploded view of an arrangement of a power module and a multifunctional frame arranged above it, according to an example embodiment of the present invention.

FIG. 4 is a sectional view of the arrangement of a power module and a multifunctional frame arranged above it in the Z direction, according to an example embodiment of the present invention.

FIG. 5 is a sectional drawing of the arrangement of a power module and a printed circuit board arranged above it in the Z direction, according to an example embodiment of the present invention.

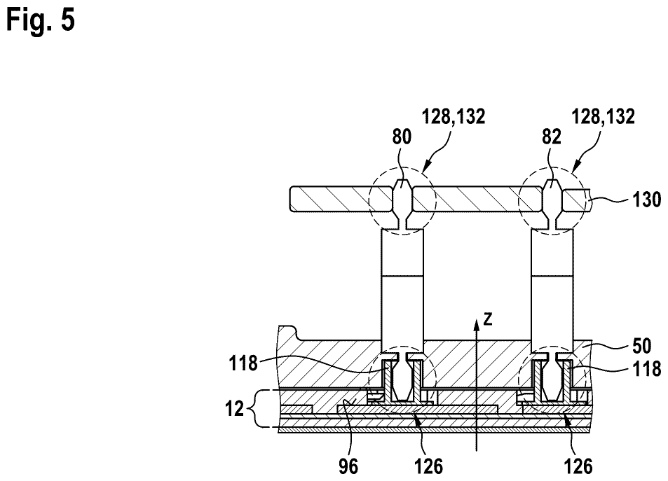

### DETAILED DESCRIPTION OF EXAMPLE EMBODIMENTS

In the following description of the embodiments of the present invention, identical or similar elements are denoted by the same reference signs, and a repeated description of these elements in individual cases is dispensed with. The figures show the subject matter of the present invention only schematically.

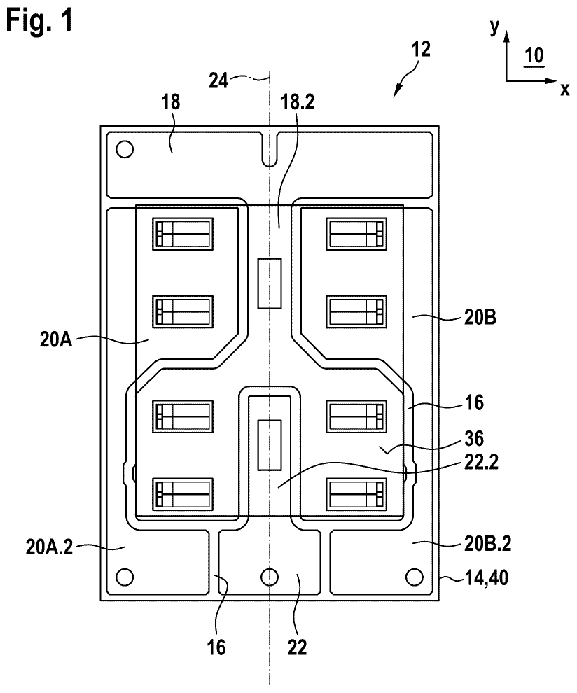

FIG. 1 shows a plan view of a power module 12, in particular of its circuit carrier 14.

The plan view according to FIG. 1 shows that a carrier substrate 40 of the circuit carrier 14 is provided with a number of conductor structures 18, 20A, 20B, 22. The circuit carrier 14 extends in an X-Y plane 10, wherein the circuit carrier 14 is provided with an electrical insulation layer 16. On said insulation layer, separated by channel-shaped interruptions, there is a first conductor structure 18, which has an external contact region 18.2. Furthermore, second conductor structures 20A, 20B are located symmetrically to a central longitudinal axis 24 of the power module 12 and opposite one another on the first circuit carrier 14. Each of the two second conductor structures 20A, 20B comprises an external contact region 20A.2, 20B. 2. Finally, a third conductor structure 22, which has at least one external contact region 22.2, is applied to the circuit carrier 14 or to its electrical insulation layer 16.

The aforementioned conductor structures 18, 20A, 20B, 22 are electrically separated from one another and are applied to the circuit carrier 14 substantially symmetrically to the central longitudinal axis 24. Position 36 denotes an active surface, and a layout surface surrounding it for the current conduction is denoted by reference sign 38. As the carrier substrate 40 of the circuit carrier 14, AMB (active metal brazing, (OFC (oxygen-free copper)/Si₃N₄/OFC)) is preferably selected.

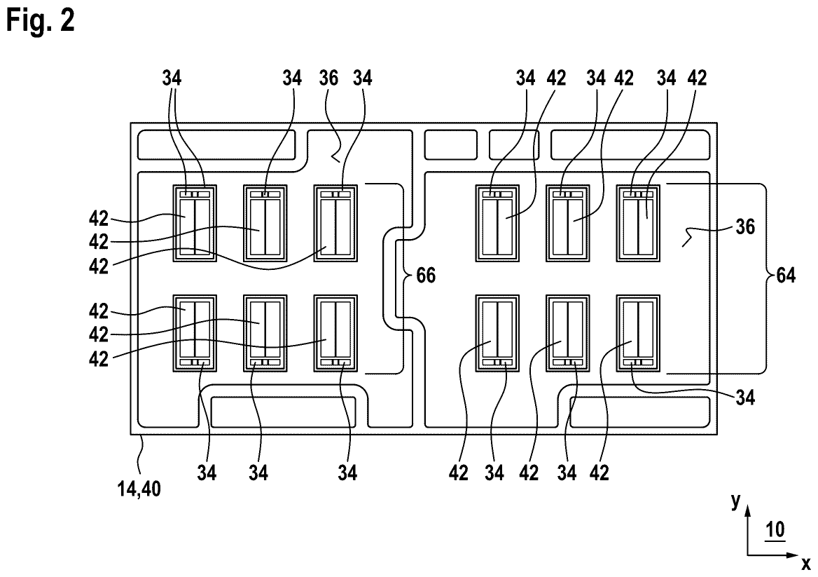

The representation according to FIG. 2 shows a plan view of the power module 12, wherein, in this schematic representation, semiconductor components 42 are arranged on active surfaces 36, which components may, for example, be transistors, MOSFETs, IGBTs, diodes, or other semiconductor components that can be used as semiconductor switches. FIG. 2 shows that a first group 64 of semiconductor components 42 is accommodated on the active surfaces 36. The individual semiconductor components 42 can, for example, be designed as MOSFETs and comprise control terminals 34 on their outer sides, via which control terminals a control, not shown in detail, of the individual semiconductor components 42 of the first group 64 of semiconductor components 42 can be effected. Analogously to the first group 64, a second group 66 of semiconductor components 42 is provided, which may also be MOSFETs, on the outer region of which control terminals 34 are formed in each case. An arrangement of the semiconductor components 42 in groups 64, 66 is not absolutely necessary; depending on the scaling, they can also be arranged individually, i.e., not in groups. The semiconductor components 42 of the second group 66 of semiconductor components 42 can be controlled from the outside via the control terminals 34, but this is not shown in detail in the representation according to FIG. 2.

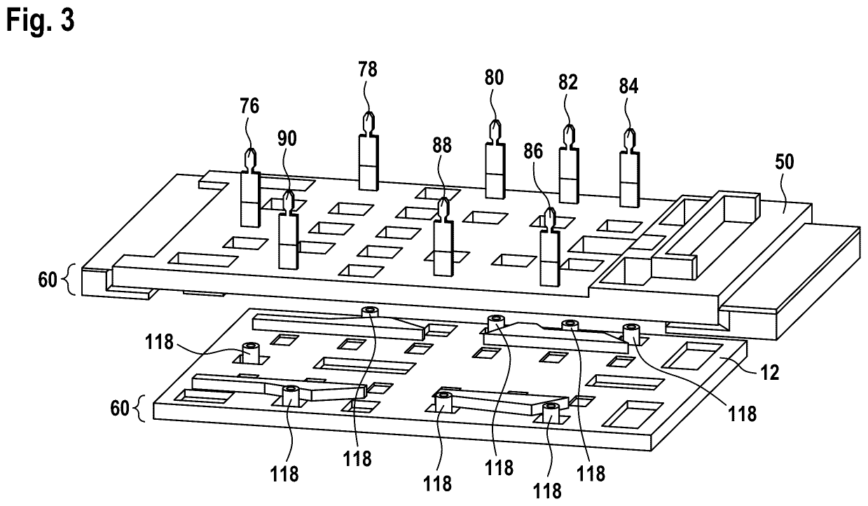

The exploded view according to FIG. 3 shows that a multifunctional frame 50 shown here is accommodated on the power module 12. The individual double-ended pins 76, 78, 80, 82, 84, 86, 88, 90, shown here lying in a drawing plane, protrude upward in the vertical direction on the upper side of the multifunctional frame 50 shown in FIG. 3. Via the double-ended pins 76-90, the sleeves 118 arranged within the multifunctional frame 50 or within the power module 12 arranged below it can be electrically contacted in a robust and simple manner. From the representation according to FIG. 3, it is further apparent that the multifunctional frame 50 represents a first level 60, while the power module 12, in this case arranged below it, forms a second level 62. Likewise, in a modification of the representation according to FIG. 3, the multifunctional frame 50 could be arranged above the power module 12, as viewed in the Z direction 54.

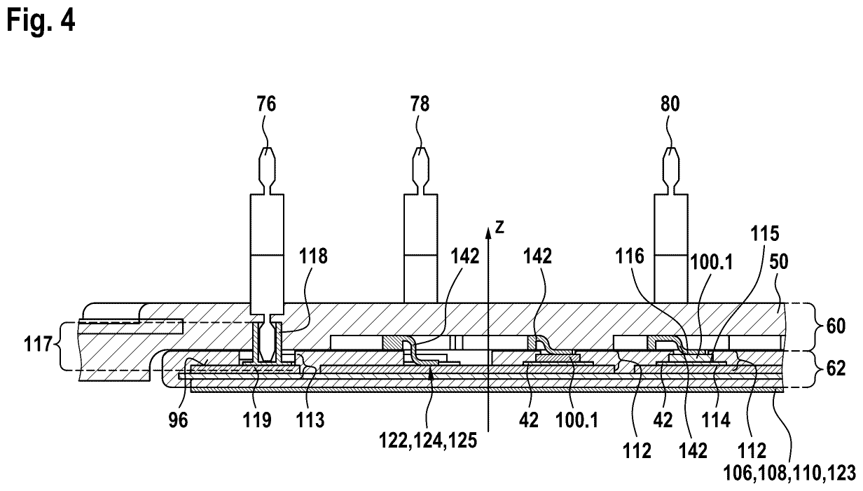

FIG. 4 shows a sectional view of the arrangement of a power module 12 and a multifunctional frame 50 arranged above it in the Z direction 54. From the representation according to FIG. 4, it is furthermore apparent that the multifunctional frame 50 represents a first level 60, while the power module 12, in this case arranged below it, forms a second level 62. FIG. 4 further shows a first welded connection 112, a second welded connection 113, a third welded connection 122, and a fourth welded connection 123. Furthermore, the first welded connection 112 has a first weld layer 114, with which the semiconductor component 42 is connected to a base 96 of the power module 12. Moreover, the first welded connection 112 has a second weld layer 115, with which the semiconductor component 42 is connected to a first spacer 100.1, and a third weld layer 116, which connects the first spacer 100.1 to a contact strip 142 of the multifunctional frame 50 so that the heat of the contact strips 142 can be dissipated via a fourth welded connection 123 or a first soldered connection 110 or an adhesive connection 108 through the base 96 to the cooling surface 106. The first welded connection 112 shown in FIG. 4 advantageously ensures efficient heat dissipation and electrical reliability.

The connection shown in FIG. 4 of the base 96 of the power module 12 to the cooling surface 106 can be variably made by the first soldered connection 110, the adhesive connection 114, or a fourth welded connection 123. All connections of the base 96 of the power module 12 to the cooling surface 106 are characterized by an efficient thermal conductivity of the heat of the contact strip 142 dissipated through the base 96 of the power module 12. These connection options also offer optimal adaptation to tolerances of the surface of the power module 12 to be contacted with the cooling surface 106, since a uniform surface contact is provided by the connection options shown in FIG. 4.

The third welded connection 122 partially shown in FIG. 4 comprises a fourth and fifth sintered layer 124, 125, not shown here, via which a second spacer 100.2 is connected to the underside of the phase bridge 136 and via which the second spacer 100.2 is connected to the base 96 of the power module 12. The second spacer, not shown here, is located on the base 96 of the power module 12 so that the heat of the phase bridge 136 can be dissipated through the base 96 via the fourth welded connection 123 or the first soldered connection 110 or the adhesive connection 108 to the cooling surface 106.

A sleeve connection 117 shown in FIG. 4 has a second welded connection 113 with a sixth weld layer 119, wherein the sleeves 118 shown in FIG. 4 are connected to the base 96 of the power module 12. Within each sleeve 118, there is a double-ended pin 76, 78, wherein a first side 126 of the double-ended pin 76, 78 is inserted into the sleeve 118. In addition, the double-ended pins 76, 78, 80 shown in FIG. 4 have a second side 128, which is designed to be plugged together with a printed circuit board 130 located in the multifunctional frame 50. The second welded connection 113 can alternatively be replaced by a second soldered connection 113 with a solder layer.

FIG. 4 shows a sectional drawing of the arrangement of a power module 12 and a printed circuit board 130 arranged above it in the Z direction 54. Furthermore, two sleeve connections 117 are shown. Each sleeve connection 117 has a sleeve 118, which can be fastened to the base 96 of the power module 12, for example via a second welded connection 113 or second soldered connection 113. Within each sleeve 118, there is a double-ended pin 80, 82, wherein a first side 126 of the double-ended pin 80, 82 is inserted into the sleeve 118 and the second side 128 of the double-ended pin 80, 82 is pressed into an opening 132 of the printed circuit board 130. The first side 126 and the second side 128 of the double-ended pins 76, 78, 80, 82, 84, 86, 88, 90 may, for example, have a specific shape of the mandrel, such as a conical shape, a cylindrical shape, or a disk-shaped shape. Alternatively, the first side 126 and the second side 128 of the double-ended pins 76, 78, 80, 82, 84, 86, 88, 90 may have a different shape, thereby creating a stable and permanent connection between the components.

The present invention is not limited to the exemplary embodiments described here and the aspects emphasized therein. Rather, a plurality of modifications, which are within the scope of activities of a person skilled in the art in view of the disclosure herein, are possible within the scope of the present invention.

1-10. (canceled)

11. A power module, comprising:
a circuit carrier including a carrier substrate and an electrical insulation layer, wherein the circuit carrier has a first conductor structure with an external contact region, at least one second conductor structure with at least one external contact region, and a further, third conductor structure having at least one external contact region, the circuit carrier having semiconductor components arranged individually or in groups;
wherein the power module is assigned a multifunctional frame with a printed circuit board, wherein the groups of semiconductor components are arranged in a first level, which is spatially separated from a second level in the multifunctional frame, and the semiconductor components are electrically connected to one another by a first welded connection with an introduction of at least one first spacer, wherein the power module is electrically connected to the multifunctional frame by a sleeve connection with introduction of at least one double-ended pin and at least one sleeve.

12. The power module according to claim 11, wherein the semiconductor components are arranged on a base of the power module individually or in groups.

13. The power module according to claim 11, wherein the power module is connected to a cooling surface via: (i) an adhesive connection, or (ii) a first soldered connection, or (iii) a fourth welded connection.

14. The power module according to claim 11, wherein the power module is connected to the multifunctional frame via a second welded connection and a third welded connection.

15. The power module according to claim 14, wherein the first welded connection includes a first weld layer, a second weld layer, and a third weld layer.

16. The power module according to claim 11, wherein the multifunctional frame is arranged above or below the power module as viewed in a Z direction.

17. The power module according to 11, wherein current-carrying components, including a T+ bridge and a T− bridge, are formed one above the other or next to one another in the multifunctional frame in such a way that a low-inductive connection is formed.

18. The power module according to claim 14, wherein the at least one sleeve is connected to the power module via a second soldered connection.

19. The power module according to claim 11, wherein each of the at least one double-ended pin has a first side and a second side.

20. A method for producing a power module, comprising:
providing a first conductor structure with a first contact region, at least one second conductor structure with at least one external contact region, and a further, third conductor structure having an external contact region;
assigning a multifunctional frame with a printed circuit board to the power module; and
making an electrical connection of the power module to the multifunctional frame via at least one double-ended pin, wherein groups of semiconductor components are arranged in a first level, which are spatially separated from a second level in the multifunctional frame, and wherein contact faces contacting the groups of semiconductor components are arranged in the second level.
